(19) United States
(12) Patent Application Publication
(10) Pub. No.: US 2025/0111118 A1
(43) Pub. Date: Apr. 3, 2025

(54) MICROBITSTREAMS FOR REDUCING FIELD PROGRAMMABLE GATE ARRAY CONFIGURATION TIME

(71) Applicant: The United States of America, as Represented by the Secretary of the Navy, Crane, IN (US)

(72) Inventors: Christopher Sozio, Bloomington, IN (US); Grant Skipper, Annandale, VA (US); Adam Duncan, Bloomington, IN (US)

(73) Assignee: The United States of America, as represented by the Secretary of the Navy, Arlington, VA (US)

(21) Appl. No.: 18/782,626

(22) Filed: Jul. 24, 2024

Related U.S. Application Data
(60) Provisional application No. 63/528,541, filed on Jul. 24, 2023.

(51) Int. Cl. G06F 30/34

(52) U.S. Cl. CPC G06F 30/34

(57) ABSTRACT

Provided are methods and apparatus that provide for removing unnecessary configuration information from the bitstream to configure a field programmable gate array (FPGA) using a reduced bitstream stylized as a “microbitstream.” The method and apparatus split FPGA configuration information into two separate configurations to reduce the initial configuration while applying encryption and authentication to the initial bitstream and leverage partial reconfiguration through a bootloader to load in secondary functionalities during or after run time of the initial configuration. Encryption and authentication are also applied to secure the bitstream from tampering, cloning, and malicious insertions. The present apparatus and methods achieve significant reductions in the total configuration time of an FPGA, which is particularly useful for time-sensitive systems, thus decreasing program development costs and time spent in the design process.

### CROSS-REFERENCE TO RELATED APPLICATIONS

The present application claims the benefit of and priority to U.S. Provisional Patent Application Ser. No. 63/528,541, filed Jul. 24, 2023, and entitled “MICROBITSTREAMS FOR REDUCING FIELD PROGRAMMABLE GATE ARRAY CONFIGURATION TIME,” the disclosure of which is expressly incorporated by reference herein.

### STATEMENT REGARDING FEDERALLY SPONSORED RESEARCH OR DEVELOPMENT

The invention described herein was made in the performance of official duties by employees of the Department of the Navy and may be manufactured, used and licensed by or for the United States Government for any governmental purpose without payment of any royalties thereon. This invention (Navy Case 211676US02) is assigned to the United States Government and is available for licensing for commercial purposes. Licensing and technical inquiries may be directed to the Technology Transfer Office, Naval Surface Warfare Center Crane, email: Crane_T2@navy.mil.

### FIELD

The present disclosure relates to apparatus and methods using microbitstreams to reduce field programmable gate array (FPGA) configuration time.

### BACKGROUND

Field-programmable gate arrays (FPGAs) are programmable integrated circuits that allow for configuration after construction of the circuits. In particular, FPGAs contain an array of programmable logic blocks, and reconfigurable interconnects allowing logic blocks to be wired together. Many FPGAs can be reprogrammed to implement different logic functions, allowing for flexible reconfigurable computing.

An FPGA configuration and/or functionality is generally programmed through a configuration file, or bitstream instruction, which are programmed into the device at boot-up. In some instances, such as in time sensitive systems, the programming time during boot-up is too long due to the configuration time of the bitstream, especially if bitstream encryption and authentication are used. Current techniques to reduce the configuration times of bitstreams include configuration frame removal, compressing the bitstream, or partial reconfiguration of the FPGA fabric during run time. Often these solutions do not apply encryption or authentication to the final bitstream, which leaves the user design susceptible to tampering, cloning, and malicious insertions.

### SUMMARY

The present disclosure includes methods and apparatus for decreasing configuration time of a field programmable gate array (FPGA). The apparatus and method implement parsing of a configuration data bitstream for an FPGA into critical and secondary bitstreams, reducing at least the critical bitstream by eliminating unnecessary configuration data and/or commands to obtain a reduced bitstream, and loading the reduced bitstream into the FPGA for initial FPGA configuration.

Additional features and advantages of the present invention will become apparent to those skilled in the art upon consideration of the following detailed description of the illustrative embodiments including examples describing a best mode of carrying out the invention as presently perceived.

### BRIEF DESCRIPTION OF THE DRAWINGS

FIG. 1 illustrates a typical architecture of known FPGAs that are arranged into rows, columns, and configuration frames to define the logic elements, routing, and other hardware primitives of the FPGA according to some aspects of the present disclosure.

FIG. 2 illustrates an example of an exemplary bitstream structure used in a per-frame bitstream according to some aspects of the present disclosure.

FIG. 3 illustrates a microbitstream process for removing various Frame Address Register (FAR), no-operation (NOOP), and Frame Data Register In (FDRI) commands according to some aspects of the present disclosure.

FIG. 4. illustrates an example of an encrypted microbitstream according to some aspects of the present disclosure.

FIG. 5 illustrates an example of a microbitstream runtime process according to aspects according to some aspects of the present disclosure.

FIG. 6 illustrates configuration time results derived from testing of the present microbitstream apparatus and methods according to some aspects of the present disclosure.

FIG. 7 shows a graph illustrating the configuration times with bars to more easily show the decrease in time when using a MicroBitstream compared to other solutions according to some aspects of the present disclosure.

FIG. 8 illustrates a table showing configuration times of the noncritical functionalities including the size of the bitstream for each secondary, or non-critical, functionality according to some aspects of the present disclosure.

FIG. 9 illustrates a block diagram of an exemplary apparatus implementing microbitstreams for configuration of FPGAs according to some aspects of the present disclosure.

FIG. 10 illustrates a flow diagram of an exemplary method for implementing microbitstreams for configuration of FPGAs according to some aspects of the present disclosure.

### DETAILED DESCRIPTION

The present examples of the inventive concepts described herein are not intended to be exhaustive or to limit the present disclosure to the precise forms disclosed. Rather, the presently disclosed embodiments have been chosen to enable one skilled in the art to practice the disclosed inventive concepts.

The presently disclosed apparatus and methods solve the previously discussed problems of time sensitivity and encryption/encoding by providing a bitstream reduction technique to produce what is termed “MicroBitstreams,” (also referred to herein as a “reduced bitstream”) which are created by a processor and/or algorithm run on at least one processor (which may be external to or, alternatively, within an FPGA device) that reduces the bitstream size and leverages partial reconfiguration through a bootloader preconfigured in the FPGA to load in secondary functionalities during run time. MicroBitstreams separate the final FPGA design into secondary and critical functionalities. The critical functionality will be included in the MicroBitstream that is encoded/encrypted alongside the bootloader, which is, in turn, used to load in the secondary functionalities after boot-up through dynamic Partial Reconfiguration (PR). This bifurcation or separation reduces the total configuration frames that are needed in the MicroBitstream, therefore decreasing the boot-up time. The average decrease in total configuration time when using a MicroBitstream compared to a normal encrypted bitstream is 88.70%, and 57.61% when compared to an encrypted compressed bitstream. MicroBitstreams offer the use of FPGAs in time-sensitive systems, thus decreasing program development costs and time spent in the design process.

As further background, it is noted that a binary configuration file, or bitstream, is used to configure an FPGA's logic, routing, and clocking resources. The user can use any supported configuration interfaces in order to load the bitstream into the FPGA such as the Joint Test Action Group (JTAG) interface. A bitstream is typically made up of three sections: (1) a header; (2) configuration data, and (3) a footer. Both the header and footer contain configuration commands to write or read from the FPGA's configuration registers. The configuration registers are referenced within the bitstream by the configuration commands to begin configuration, enable the decryption engine, poll the status of the FPGA, and other operations. Configuration data contains the configuration that makes up the user design within the FPGA fabric. Due to the size of FPGAs, the configuration data within the bitstream make up the vast majority of the bitstream length.

Protecting the FPGA typically starts with securing the configuration data in the bitstream. Even though the generation of the configuration data is closed source, the user design can be recovered through reverse-engineering of the bitstream. Hence, FPGA vendors provide bitstream encryption and authentication to help protect the bitstream and prevent reverse-engineering. Bitstream authentication also ensures that only bitstreams created by the intended user can be loaded into the FPGA, or that any non-approved modification to the bitstream halts the configuration process and resets the FPGA. Encryption and authentication are important in protecting the user design, especially with FPGAs being used in high performance data centers, automotive systems, and other sensitive applications.

Bitstreams that are generated using vendor Electronic design automation (EDA) toolchains contain the configuration for the entire FPGA fabric, even if parts of the fabric are not being used by the user design. Therefore to help condense the size of bitstreams, some vendors' EDA tool chains offer the ability to compress bitstreams. For AMD-Xilinx FPGAs, bitstream compression leverages an FPGA configuration register, Multiple Frame Write Register (MFWR), to write reoccurring data in the bitstream to multiple frames. If successive configuration frames contain the same data, then bitstream compression will wrap those configuration frames into one write command to the MFWR. Bitstream compression does decrease the overall configuration time, as leveraging the MFWR allows the FPGA to write data for multiple frames without having to interpret each configuration frame individually from the bitstream. With the bitstream being smaller there is less data being sent over any of the configuration interfaces. The non-volatile memory needed to store the bitstream is also allowed to be smaller. All are benefits of using the vendor supplied bitstream compression.

Bitstream compression, however, still writes to every configuration frame whether it contains data or is empty. Hence, valuable configuration time is still spent writing unnecessary data to the FPGA fabric. On the other hand, Microbitstreams, as disclosed herein, remove unnecessary writes to the FPGA fabric by looking at the contents of each configuration frame and determining if the contents are and/or the frame is needed.

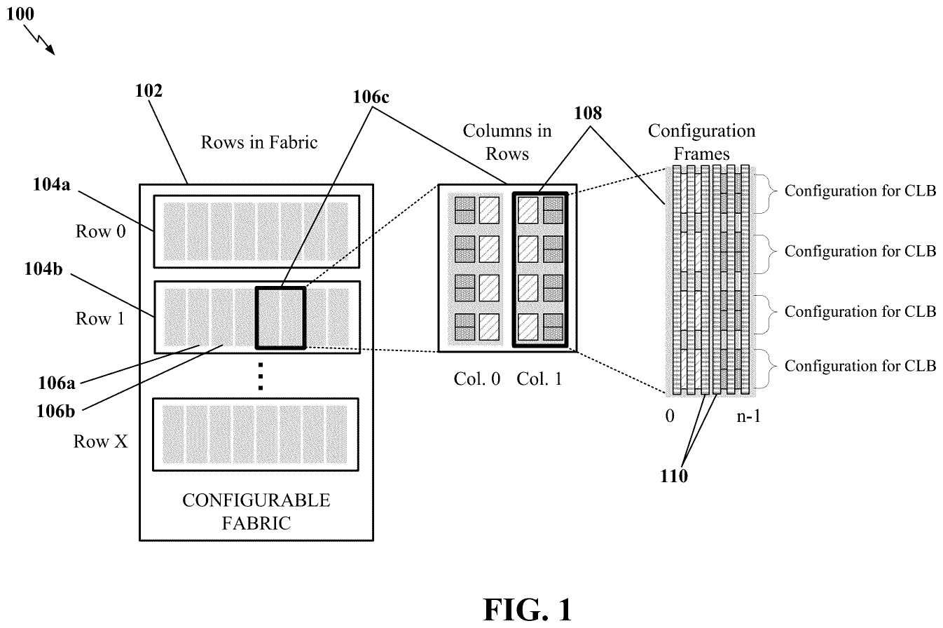

FIG. 1 illustrates a typical architecture 100 of known FPGAs, which in this example is an AMD-Xilinx FPGA. AMD-Xilinx FPGAs, in particular, are arranged into rows, columns, and configuration frames which are used to define the logic elements, routing, and other hardware primitives of the FPGA. As shown in FIG. 1, the architecture 100 can be visualized as an “X” series of rows 104 illustrated by reference numbers 104a, 104b, etc. Within each row 104 lies a series of columns (e.g., 106a, 106b, 106c (the latter of which is shown as having two columns in a “column” for further illustration purposes)). The columns 106 may then each be further divided into configuration frames as shown at 108. Configurable Logic Blocks (CLBs), Block RAM (BRAM), clocking resources, routing resources, and specific hardware primitives vertically span the entirety of each column. CLBs contain Look-Up Tables (LUTs), Flip-Flops (FFs), and other hardware resources to make up the logic behind the user design. Configuration frames are the smallest addressable memory in the FPGA fabric and are aligned vertically in columns (See e.g., 110). Multiple configuration frames are used to configure the resources spanning the column.

The presently disclosed apparatus and methods employ a reduced bitstream (stylized or termed herein as “microbitstreams,” “Microbitstreams,” or “MicroBitstreams”) technique that provides an encrypted reduced bitstream to decrease the boot-up time of a FPGA. With the fabric of modern FPGAs growing with every new device, the time it takes to configure the FPGA fabric increases consequently. Since the entire fabric cannot be used and typically sections of the fabric are not used by the design, a portion of the configuration time is spent configuring the fabric to all zeroes. MicroBitstreams cut the unused configuration data from the bitstream, therefore minimizing the bitstream. MicroBitstreams also leverage a bootloader to configure the FPGA at run-time allowing the initial design included in the MicroBitstream to include only the necessary, or critical, logic at boot-up. The MicroBitstream includes encryption and authentication to protect the design from IP theft/cloning, Trojan insertion, and tamper/modification. Additionally, MicroBitstreams allow the boot-up time of an FPGA to be reduced significantly including the design to still be protected from malicious entities.

The present disclosure using MicroBitstreams provides separation of the FPGA design into secondary and critical functionalities. The critical functionalities are included in the MicroBitstream alongside a bootloader, which is used to load in the secondary functionality after boot-up through dynamic Partial Reconfiguration (PR). This separation reduces the total number of configuration frames that are needed in the MicroBitstream therefore decreasing the boot-up time. The user bitstream may be generated using a vendor EDA toolchain, although the invention is not limited to such, and contains the critical functionality and boot loader that will go through the MicroBitstreams process. In the microbitstream process, an initial step is removal of unnecessary configuration frames from the bitstream. The remaining configuration frames are encrypted with the same user specified symmetric key that will be stored in the FPGA. At boot-up the MicroBitstream is decrypted and loaded into the FPGA starting the critical functionality of the FPGA design and the boot loader. The boot loader then programs in the remaining functionality (e.g., the secondary functionalities) of the FPGA design at run-time, thus leveraging the partial reconfiguration process of modern FPGAs. The reduced number of configuration frames within the MicroBitstream allows the FPGA to boot-up at a much faster rate than previously capable. Hence, more time-critical applications can include FPGAs in their solution.

Dynamic partial reconfiguration (PR) is used to configure sections of the FPGA during run time. User designs are then able to be updated on the fly, creating a dynamic environment for the user. AMD-Xilinx FPGA's PR, for example, is accomplished through the use of an Internal Configuration Access Port (ICAP) hard IP. The ICAP is a 32-bit wide configuration interface which can be accessed through internal resources in the FPGA. The ICAP can individually address each configuration frame in the FPGA like any other configuration interface. With PR the FPGA does not halt the current design while it is configuring the FPGA, which allows a secondary configuration to be applied during run time.

During the design stage, a user defines what is considered critical configuration information/design and what will be the secondary configuration information/design. The two portions of the design are carefully partitioned to prevent the configuration in the secondary bitstream from writing over the previous configuration of the critical configuration (i.e., information that is in the MicroBitstream). Partitioning the fabric of current FPGAs may be easily accomplished using vendor provided Electronic Design Automation (EDA) toolchains. Most state-of-the-art FPGA vendors include tools within their EDA toolchain to constrain portions of a user design to specific locations in the FPGA fabric. The EDA toolchains also include Design Rule Checks (DRCs) to help ensure that the two designs are partitioned correctly and will not write over one another. Therefore, a user is able to quickly and easily partition the two separate parts of the design (critical functionality and secondary functionality). Thus, loading in a secondary bitstream at run time will not write over the previous functionalities causing the design to fail. The presently disclosed MicroBitstreams leverages partial reconfiguration through a bootloader to program the secondary configuration into the FPGA at run-time. The ICAP is used by the bootloader to load in that secondary bitstream.

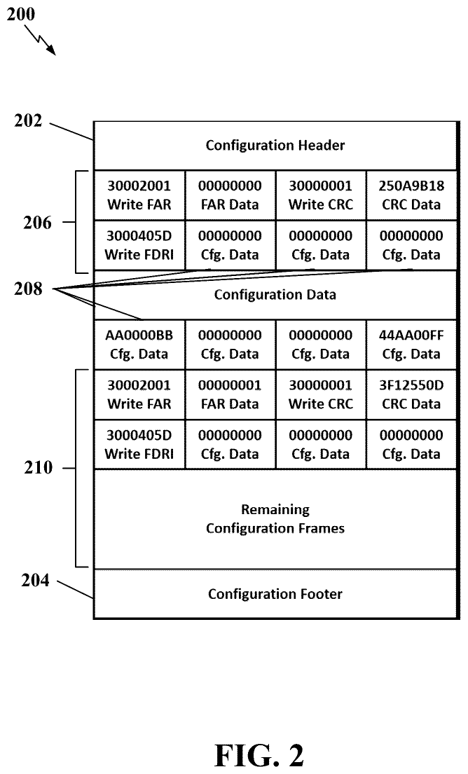

Before generating the bitstream, the presently disclosed MicroBitstreams forces the use of individually addressed configuration frames within the generated bitstream. FIG. 2, as an example, illustrates an exemplary per-frame bitstream shown at 200. Individually addressed configuration frames form the per-frame bitstream as shown at 202. Per-frame bitstreams ensure the process of evaluating and eliminating unused configuration frames becomes a significantly faster and easier process. In aspects, the per-frame bitstreams such as 200 contain the same configuration header 202 and footer 204 as a non per-frame bitstream, but the configuration is broken up into the individual configuration frames. Each configuration frame, as shown at 206 as an example, is broken up by writes to the Frame Address Register (FAR) which addresses the target configuration frame in the FPGA. Following the write to the FAR is a Cyclic Redundancy Check (CRC) and a write to the Frame Data Register In (FDRI). Configuration data 208 for the specified frame address occurs in the frame after the FDRI (shown in range 206 as 3000405D Write FDRI). The length of the configuration data is dependent upon the FPGA device that is being used in the system. Further remaining configuration frames and addressing are shown in the range of lines at 210.

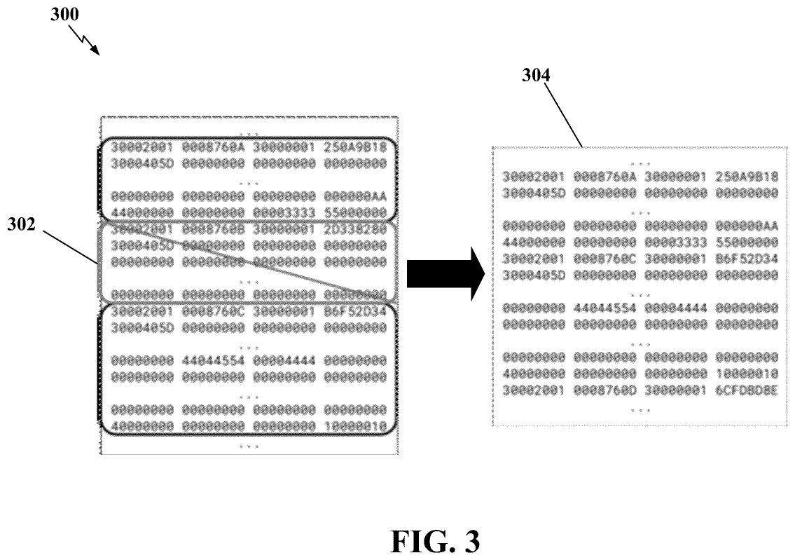

FIG. 3 illustrates the microbitstream process 300 for removing various Frame Address Register (FAR), no-operation (NOOP), and Frame Data Register In (FDRI) commands. In a particular example, the presently disclosed MicroBitstream process replaces every CRC command and following data word with no-operation (NOOP) commands. Because the MicroBitstream will eventually be encrypted, the authentication tag will verify if data has been dropped or modified in any way making the CRC check redundant. Once all CRC checks are removed, a data parser configured and/or built for MicroBitstreams will determine what configuration data is necessary to keep and what data can be removed. The data parser will begin at the beginning of the bitstream (ideally the first configuration frame in the FPGA) and step through each configuration frame. If the configuration data is empty (i.e., all zeros), then the write to that configuration frame is removed from the bitstream. Therefore the FAR, NOOP, and FDRI commands (see e.g., 302) are removed in conjunction with the configuration data to achieve a smaller frame 304 as shown in FIG. 3. In aspects of this process, the MicroBitstream parser steps through each configuration frame in the per-frame bitstream (shown at the left of FIG. 3) to determine if the configuration data is empty or not. If the configuration data is empty then the parser will exclude the write to the configuration frame from the MicroBitstream as shown at frame 304.

To prepare the MicroBitstream for encryption, the Control Register 0 (CTL0) command in the bitstream will need to be updated to enable the internal decryption engine. The DEC bit in the CTL0 data word needs to be set to a one to enable the AES decryptor. The CTL0 command exists in both the header and footer of the bitstream, thus both commands will need to be changed. If the AES symmetric key for the FPGA is programmed into the eFUSE, then the CTL0 command will also need to set the EFUSE KEY bit to a one. The default symmetric key storage is the battery-backed RAM (BBRAM). Every write to either the CTL0 or CTL1 registers must have a write to the MASK register before it, hence the MASK command must be updated too. The MicroBitstream is now ready to be encrypted using the specified encryption algorithm Advanced Encryption Standard-Galois Counter Mode (AES-GCM).

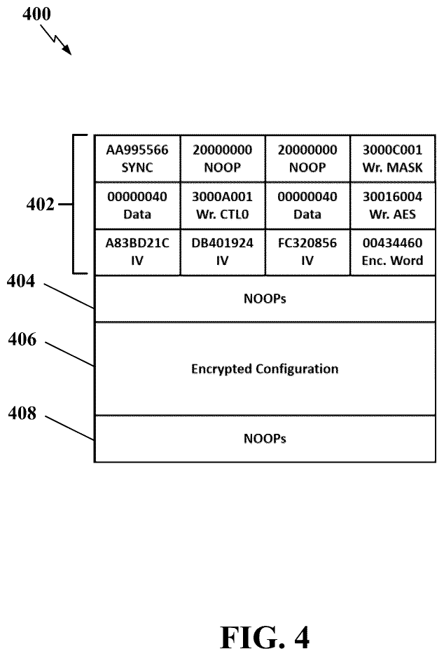

FIG. 4 illustrates an example of an encrypted microbitstream 400 according to aspects of the present disclosure. In some particular aspects, an Ultrascale+FPGA utilizes the AES-GCM algorithm to provide encryption and authentication to bitstreams. An encrypted bitstream is structured differently than an unencrypted bitstream in that it will contain an unencrypted header and an encrypted header. The unencrypted header still starts with the SYNC word (e.g., 0xAA995566) as every other AMD-Xilinx bitstream as may be seen at the start of the frame range denoted with 402. Next, commands are a write to the MASK and CTL0 registers to enable the decryption engine. Following is then a write to the AES IV register, which provides the initialization vector (IV) and the total number of encrypted words. The encrypted word total is typically dependent upon the FPGA device, but since the MicroBitstream has removed configuration, the encrypted word length will depend on how much configuration data is left to encrypt. Following the AES IV command are a number of NOOPs (e.g., 56 NOOPs) shown at 404 to allow time for the FPGA decryption engine to initiate. In one example, the remaining data (e.g., 406) in the bitstream may be encrypted using the Galois Counter (GCTR) Mode function. In still other aspects, it is noted that AMD-Xilinx introduced a new authentication algorithm into Ultrascale and Ultrascale+bitstreams if such devices are used. These algorithms utilize X-GHASH checksums that occur every 8^{th} word in the encrypted bitstream. Since checksums are generated through a combination of the previous checksum and ciphertext, the checksums are generated on the fly when encrypting the bitstream. Also while encrypting the bitstream, the final authentication tag will be generated using the Galois Hash (GHASH) function. The final tag will be placed at the end of the generated ciphertext from the GCTR function. The encrypted word total will be updated due to the addition of the X-GHASH checksums, but will not include the final tag. Finally, the bitstream is ended with further NOOPs as shown at 408.

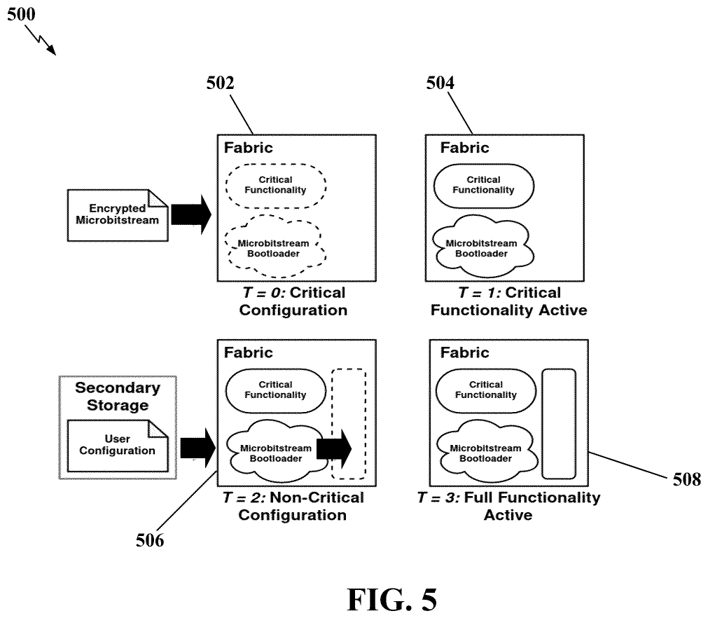

FIG. 5 illustrates an example of the microbitstream runtime process 500 according to some aspects. As shown at block 502, programming the bootloader and critical functionality into the fabric of the FPGA is performed with the encrypted MicroBitstream loaded into the FPGA at time T=0 or T0 (which is not necessarily in units of time but can also be indicative of a time sequence of events). It is further noted that any of a number of configuration interfaces can be used to program the FPGA. At block 504, which is time T=1 or TI, the critical functionality and MicroBitstream bootloader are both active and performing the necessary tasks at boot up. Next, the secondary user configuration or secondary functionality is loaded in from secondary storage using a MicroBitstream bootloader at a time T=2 or T2, which is shown by block 506. Finally, at a time T=3 or T3 shown by block 508, the full functionality of the user design is active, enabled, and performing all tasks. The configuration flow allows a much faster initial configuration time for the MicroBitstream.

To ensure that MicroBitstreams can decrease the total configuration times of AMD-Xilinx FPGAs, for example, multiple tests of the MicroBitstream process were performed using different designs for the Kintex Ultrascale+KCU116 evaluation board (xcku5p-2ffvb676c). The efficacy of the Microbitstreams was tested by measuring the time required to configure a KCU116 FPGA fabric. Timing results were observed while configuring the FPGA over a Joint Test Action Group (JTAG) configuration interface at a frequency of 15 MHz and captured by a Saleae Logic Pro 16 logic analyzer.

In operation, three separate designs were developed to test the MicroBitstreams capability. Each design contained critical functionality and the previously discussed bootloader to load in the secondary functionality. The first design starts with a LED on as the critical functionality, and then after the bootloader loads in the secondary functionality at run time the LED is turned off (LED On to Off). The second design is similar but starts with the LED off and then turns it on after loading the secondary functionality during run time (LED Off to On). The final design consists of an LED toggle controller through a Universal Asynchronous Receiver/Transmitter (UART) for the critical functionality, and then an Arbiter Physically Unclonable Function (PUF) for the secondary functionality. For each design, multiple bitstreams were generated to create a normal encrypted bitstream, compressed encrypted bitstream, and a per-frame bitstream. Both the normal and compressed encrypted bitstreams were not modified, but the per-frame bitstream was used to create the encrypted MicroBitstream. Unencrypted bitstreams were also generated for testing of each design and compression to highlight the timing decrease of MicroBitstreams compared to unencrypted bitstreams as well. To program the FPGA with each bitstream, the AMD-Xilinx Vivado toolchain was used to load each bitstream into the FPGA through the USB to JTAG onboard circuitry. Each bitstream utilized the on-chip decryption and authentication engine.

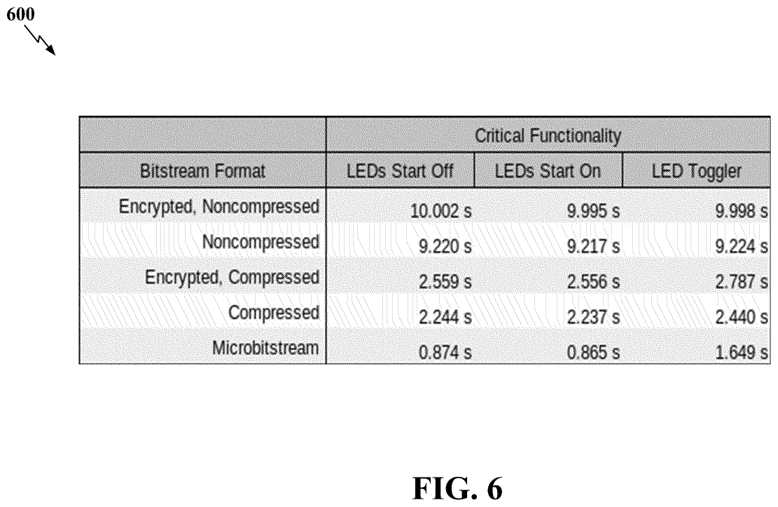

As an example, FIG. 6 illustrates configuration time results derived from the testing described above. In the table 600, each bitstream time is shown for all three designs. The configuration times were measured by a logic analyzer connected to the JTAG configuration interface of the FPGA. The timing was measured between a SYNC word being received and when a DONE signal goes high. As may be seen in table 600, the configuration times for the initial bitstreams for each of Encrypted and Unencrypted non-compressed, Encrypted and Unencrypted Compressed, and the presently disclosed MicroBitstream. As may be further seen, the configuration time for the MicroBitstream, on average, decreases the configuration time by 88.70% compared to a normal encrypted bitstream, and 57.61% compared to an encrypted compressed bitstream.

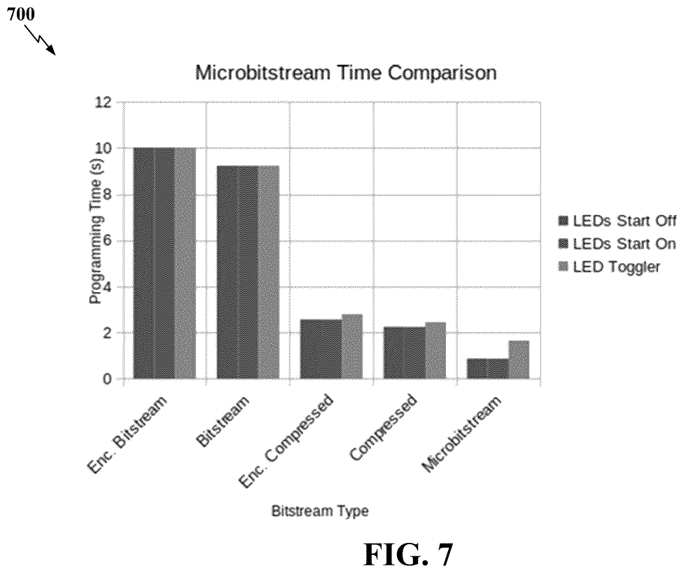

FIG. 7 shows a graph 700 illustrating the configuration times with bars to more easily show the decrease in time when using a MicroBitstream compared to other solutions. In particular, graph 700 provides a visual comparison for JTAG programming of critical functionality. It is noted that there is a relative similarity in unencrypted and encrypted bitstreams, regardless of design. However, the presently disclosed targeted bitstream reduction enables a very large time improvement over these bitstreams, and also a significant time improvement over compressed bitstreams.

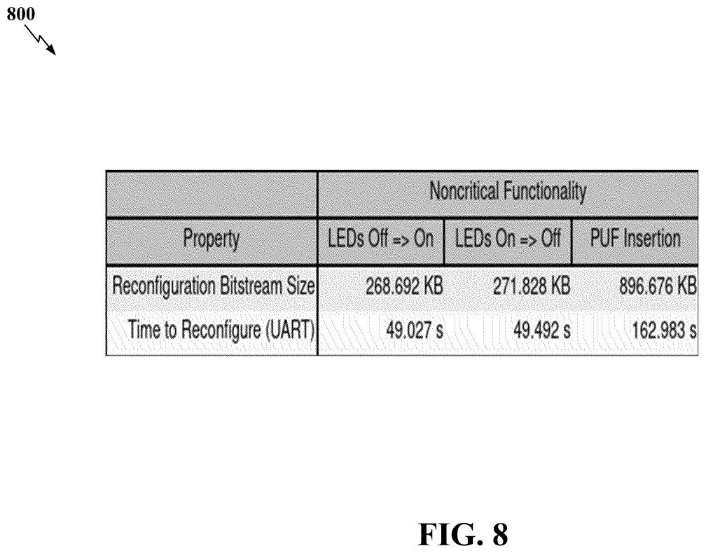

FIG. 8 illustrates a table showing configuration times of the noncritical functionalities including the size of the bitstream for each secondary, or non-critical, functionality. It is noted there that after each MicroBitstream is programmed into the FPGA, the secondary bitstream would be loaded in through the disclosed MicroBitstream bootloader. The bootloader may be connected to an external UART interface to allow easy loading of the secondary configuration data. The UART interface uses a baud rate of 115200 to communicate with a lab workstation. The workstation utilizes a Python script to send the secondary functionality to the MicroBitstream bootloader.

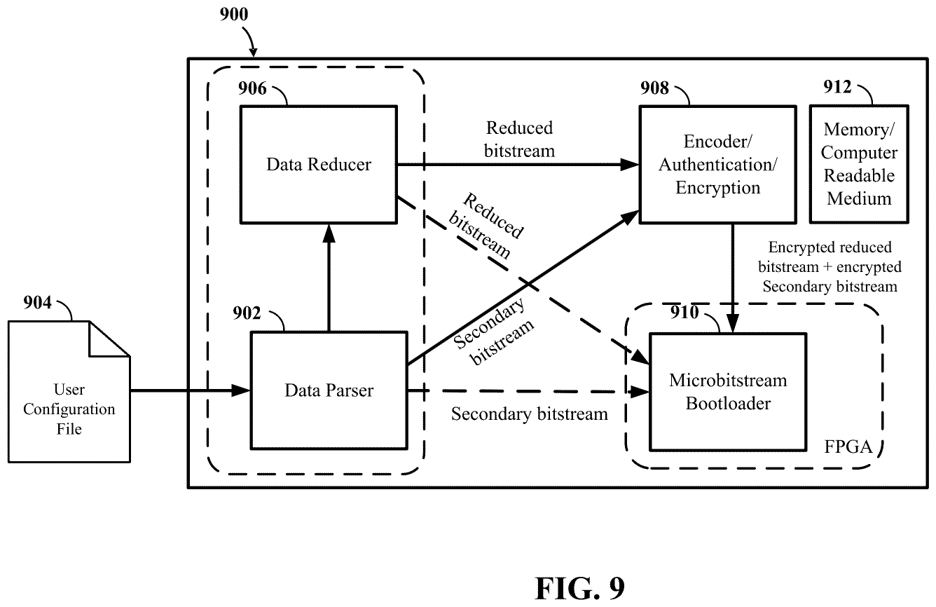

FIG. 9 illustrates a block diagram of an exemplary apparatus 900 implementing microbitstreams for configuring FPGAs according to some aspects of the present disclosure. In this example, apparatus 900 may be a processing device (i.e., one or more processors) or, in other aspects, an FPGA or a portion thereof. The apparatus 900 includes a data parser 902 configured to parse or split a configuration bitstream (e.g., user configuration file 904) and to cause separation of the configuration bitstream into at least one critical bitstream and at least one secondary bitstream. In aspects, the data parsers 902 parses the configuration data bitstream by stepping through each configuration frame in the configuration data bitstream to determine if configuration data in each respective configuration frame is empty or not. For each configuration frame that is determined to be empty, such frames are then further classified as being unnecessary configuration data or commands that can be removed as discussed above. In yet further aspects, the data parser 904 may be configured to begin at the beginning of the bitstream (ideally the first configuration frame in the FPGA) and step through each configuration frame. If the configuration data is empty (i.e., all zeros), then the write to that configuration frame will be removed from the bitstream. In some other examples, FAR, NOOP, and FDRI commands may be removed in conjunction with the configuration data to achieve a smaller frame 304 as shown in FIG. 3.

Further the apparatus 900 includes a data reducer 906 that reduces the critical bitstream and to a smaller or smallest form (i.e., MicroBitstreams) by removing unnecessary configuration information (configuration data and/or commands as discussed earlier) from the bitstream to obtain a reduced bitstream (e.g., MicroBitstream). In aspects, the data reducer 906 is configured to eliminate the at least one of unnecessary configuration data or commands to obtain the reduced bitstream by excluding writing the at least one of unnecessary configuration data or commands into the reduced bitstream. As seen, the reduced bitstream is output to an encoder/authentication/encryption module or software or firmware 908 that applies encoding and/or encryption to the reduced bitstream. In other examples, the data reducer may output the reduced bitstream to a bootloader 910 as shown with a dashed connection. The bootloader 910, in turn, loads the reduced bitstream to the FPGA to be first executed for starting configuration of the FPGA. Of further note, although the data parser 902 and data reducer 906 are shown as separate portions, these portions, modules or software may be implemented as a single unit, module, software or algorithm that accomplishes the generation of reduced bitstream as shown by the dashed box around these portions 902 and 906.

Apparatus 900 further includes the bootloader 910 that is configured to load the reduced bitstream into an FPGA as mentioned above. In some aspects, the bootloader 910 may be part of an FPGA as indicated by the dashed box or loaded into the FPGA prior to or concurrent with the reduced bitstream in some aspects. Furthermore, it is noted that the data parser 902 outputs the secondary bitstream, either to the encoder/authentication/encryption module 908 for encoding, authentication, and/or encryption of the secondary bitstream for subsequent input to the bootloader 910, which loads the secondary bitstream to FPGA after the reduced bitstream is running for FPGA fabric configuration (i.e., the FPGA is running) or may also wait until the reduced bitstream has finished running in other aspects. The secondary bitstream data (e.g., secondary storage/user configuration data) is loaded to the FPGA by the bootloader 910 after the initial, critical configuration of the FPGA has been performed and running.

It is noted that one or more of the portions of apparatus 900 (e.g., 902, 906, 908, and/or 910) may constitute one or more processors that further may execute software or general processing, including the execution of software or one or more computer implementatble instructions stored in a memory or computer-readable medium 912. As used herein, software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software, when executed by the apparatus 900, causes the apparatus to perform the various functions described herein for any particular apparatus. The computer-readable medium and/or memory 912 may also be used for storing data that is manipulated by the processing elements (e.g., 902, 906, 908, and/or 910) when executing software.

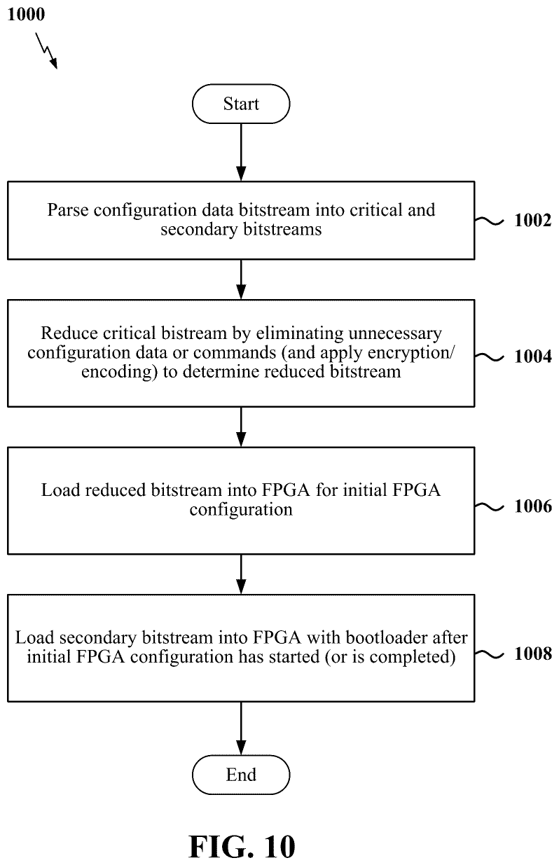

FIG. 10 illustrates a flow diagram 1000 of an exemplary method for implementing microbitstreams for configuration of FPGAs according to some aspects of the present disclosure. As shown, the method 1000 includes first parsing an FPGA configuration data bitstream into critical and secondary bitstreams as shown in block 1002. Next, method 1000 includes reducing at least the critical bitstream by eliminating unnecessary configuration data and/or commands to obtain a reduced bitstream (e.g., microbitstream) as shown in block 1004. The processes of block 1004 may also including encoding and/or encrypting the reduced bitstream.

Next, method 1000 includes loading the reduced bitstream into the FPGA for initial FPGA configuration as shown in block 1006. Once the initial configuration is completed using the reduced bitstream, flow proceeds to block 1008 where the secondary bitstream is loaded into the FPGA, such as with a bootloader as discussed previously, after initial FPGA configuration is started (or, alternatively, when complete) and the FPGA is running.

In some aspects, it will apparent from the above discussion that the presently disclosed reduced bitstreams (i.e., MicroBitstreams) provide for separating FPGA design into two partitions to initially reduce the amount of configuration within the MicroBitstream. The empty configuration is then removed and not compressed like other solutions use to decrease the size of the bitstream. MicroBitstreams also includes encryption and authentication to the bitstream, ensuring the user design is secure. With most time-sensitive applications existing in critical systems the user design needs to be secured to prevent modifications and cloning.

It is noted that the presently disclosed MicroBitstreams relate to other known bitstream size reduction techniques using compression. In particular, the known techniques apply compression using device supplied commands allowing for easy compression and requires no extra circuitry for decompression. The techniques also leverage partial reconfiguration to allow the initial, or static, bitstream to be compressed further than originally allowed. MicroBitstreams, however, do not utilize the device-supplied commands for compression, but instead remove configuration data that is empty, and applies encryption and authentication that is not applied in the known compression techniques.

Furthermore, the present methods and apparatus afford decrease of the total configuration time of modern FPGAs, and provide security for the user design through encryption and authentication. This enables the use of FPGAs in time-sensitive systems where typically ASICs are developed and used. Systems are then able to utilize FPGAs to develop and produce a solution quicker and cheaper than before.

Although the presently disclosed inventive concepts have been described in detail with reference to certain preferred embodiments and examples, variations and modifications exist within the spirit and scope of the invention as described and defined in the following claims.

What is claimed is:

1. A method for decreasing configuration time of a field programmable gate array (FPGA) comprising:
parsing a configuration data bitstream for an FPGA into critical and secondary bitstreams;
reducing the critical bitstream by eliminating at least one of unnecessary configuration data or commands to obtain a reduced bitstream; and
loading the reduced bitstream into the FPGA using a bootloader for starting an initial FPGA configuration.

2. The method of claim 1, wherein parsing the configuration data bitstream comprises:
stepping through each configuration frame in the configuration data bitstream to determine if configuration data in each respective configuration frame is empty or not, wherein each configuration frame that is determined to be empty is further classified as being the at least one of unnecessary configuration data or commands.

3. The method of claim 2, wherein eliminating the at least one of unnecessary configuration data or commands to obtain the reduced bitstream includes excluding writing the at least one of unnecessary configuration data or commands into the reduced bitstream.

4. The method of claim 1, further comprising:
loading the secondary bitstream into the FPGA after the initial FPGA configuration is running.

5. The method of claim 4, further comprising;
loading the secondary bitstream into the FPGA with the bootloader.

6. The method of claim 1, wherein the bootloader is loaded into the FPGA for use in loading the reduced bitstream into the FPGA.

7. The method of claim 1, further comprising:
applying at least one of encryption, encoding, or authentication to the reduced bitstream prior to loading into the FPGA with the bootloader.

8. An apparatus for decreasing configuration time of a field programmable gate array (FPGA) comprising:
a data parser configured to separate configuration data bitstream for an FPGA into critical and secondary bitstreams;
a data reducer configured to reduce at least the critical bitstream by eliminating unnecessary configuration data and/or commands to obtain a reduced bitstream; and
a bootloader configured to load the reduced bitstream into the FPGA for initial FPGA configuration.

9. The apparatus of claim 8, wherein the data parser is further configured to:
parse the configuration data bitstream by stepping through each configuration frame in the configuration data bitstream to determine if configuration data in each respective configuration frame is empty or not, wherein each configuration frame that is determined to be empty is further classified as being the at least one of unnecessary configuration data or commands.

10. The apparatus of claim 9, wherein the data reducer is configured to eliminate the at least one of unnecessary configuration data or commands to obtain the reduced bitstream by excluding writing the at least one of unnecessary configuration data or commands into the reduced bitstream.

11. The apparatus of claim 8, further comprising:
the bootloader configured to load the secondary bitstream into the FPGA after the initial FPGA configuration is running.

12. The apparatus of claim 8, wherein the bootloader is loaded into the FPGA for use in loading the reduced bitstream into the FPGA.

13. The apparatus of claim 8. further comprising:
an encryption/authentication/encoding module configured to apply at least one of encryption, encoding, or authentication to the reduced bitstream.

14. A non-transitory medium configured to store one or more computer implementatble instructions for decreasing configuration time of a field programmable gate array (FPGA), the instructions causing at least one processor to:
parse a configuration data bitstream for an FPGA into critical and secondary bitstreams;
reduce the critical bitstream by eliminating at least one of unnecessary configuration data or commands to obtain a reduced bitstream; and
load the reduced bitstream into the FPGA using a bootloader for starting an initial FPGA configuration.

15. The non-transitory medium of claim 14, further storing instructions causing the at least one processor to:
parse the configuration data bitstream by stepping through each configuration frame in the configuration data bitstream to determine if configuration data in each respective configuration frame is empty or not, wherein each configuration frame that is determined to be empty is further classified as being the at least one of unnecessary configuration data or commands.

16. The non-transitory medium of claim 15, further storing instructions causing the at least one processor to:
eliminate the at least one of unnecessary configuration data or commands to obtain the reduced bitstream includes excluding writing the at least one of unnecessary configuration data or commands into the reduced bitstream.

17. The non-transitory medium of claim 14, further storing instructions causing the at least one processor to:
load the secondary bitstream into the FPGA after the initial FPGA configuration is running.

18. The non-transitory medium of claim 17, further storing instructions causing the at least one processor to:
load the secondary bitstream into the FPGA with the bootloader.

19. The non-transitory medium of claim 14, further storing instructions causing the at least one processor to:
load the bootloader into the FPGA for use in loading the reduced bitstream into the FPGA.

20. The non-transitory medium of claim 14, further storing instructions causing the at least one processor to:
apply at least one of encryption, encoding, or authentication to the reduced bitstream prior to loading into the FPGA with the bootloader.
